(19) United States
(12) Patent Application Publication
(10) Pub. No.: US 2012/0125402 A1
(43) Pub. Date: May 24, 2012

(54) SOLAR CELL MOUNTING SYSTEM

(76) Inventors: Kurt Schatz, Newmarket (CA); Dominic DiBlasio, Queensville (CA); Austin O'Neill, Midland (CA); Thomas P. Frommer, Mount Albert (CA); Stephen James Caron, Aurora (CA); Samuel R. Baruco, Aurora (CA)

(21) Appl. No.: 13/303,626

(22) Filed: Nov. 23, 2011

Related U.S. Application Data
(60) Provisional application No. 61/416,851, filed on Nov. 24, 2010.

(51) Int. Cl. H01L 31/052; H01R 24/00

(52) U.S. Cl. 136/246; 439/626

(57) ABSTRACT

A solar cell assembly includes a light concentrator attached to one face of a solar cell. The solar cell is attached to an electrical connector having an insulating substrate, a first electrically conductive terminal including a flat plate portion mounted to the insulating substrate, and a second electrically conductive terminal mounted to the insulating substrate. The second terminal has a U-shaped plate portion that partially circumscribes the first terminal, including opposing first and second legs and a web interconnecting the first and second legs. Each leg includes a flexibly resilient wing, the two wings being disposed in opposing relationship. The solar cell is interposed between the first terminal and the wings of the second terminal such that the first terminal abuts one face of the solar cell and the wings of the second terminal abut exposed, spaced apart, opposing perimeter areas of the other face of the solar cell, with the wings resiliently coupling the solar cell to the first and second terminals.

### FIELD OF THE INVENTION

The invention relates to the art of solar panel systems, and in particular to systems for mounting and electrically connecting solar cells.

### BACKGROUND OF THE INVENTION

Solar cells are basically electronic devices which provide an output current. Like most electronics devices, solar cells have been conventionally soldered onto printed circuit boards utilizing conventional electronic assembly equipment and soldering processes.

In order to deploy solar cells en masse, it is desirable to reduce the cost of the solar cell panel, including its manufacturing and assembly costs. In particular, it would be desirable to eliminate the printed circuit board with its attendant assembly and soldering costs. At the same time, the alternative mounting system must still cope with dissipating excess heat generated by the solar cell, which has conventionally been controlled by conducting excess heat via the printed circuit board.

### SUMMARY OF THE INVENTION

According to one aspect of the invention an electrical connector is provided for mounting a solar cell having first and second opposing faces. The connector includes an insulating substrate; a first electrically conductive terminal including a flat plate portion mounted to the insulating substrate; and a second electrically conductive terminal mounted to the insulating substrate. The second terminal has a U-shaped plate portion that partially circumscribes the first terminal, the U-shaped portion having opposing first and second legs and a web interconnecting the first and second legs. Each leg includes a flexibly resilient wing, the two wings being disposed in opposing relationship so as to provide a resilient coupling member when a solar cell is interposed between the first terminal and the wings of the second terminal such that the first face of the solar cell abuts the first terminal and a portion of the second face of the solar cell abuts the wings of the second terminal.

The first conductive terminal preferably includes flat-domed projections extending from the flat plate portion.

The first and second terminals are preferably adhesively bonded to the insulating substrate. The insulating substrate may be a slab or layer of mica.

The wings may be formed in a variety of ways. In one embodiment, each wing has two bends therein to form a staircase pattern, the staircase pattern having a distal lip that is disposed in a different plane than the flat plate portion of the first terminal. In another embodiment each wing has a single bend therein to form a distal lip that is disposed in a different plane than the flat plate portion of the first terminal. And in another embodiment each wing is formed as a straight extension of the corresponding first or second leg, the wing having a distal lip that is disposed in a different plane than the flat plate portion of the first terminal when the solar cell is mounted in the connector. In preferred embodiments, the distance between an uppermost surface of the first terminal and the lip is less than the thickness of the solar cell, whereby the wing may function as a leaf spring to consistently apply pressure to the electrically conductive faces of the solar cell.

Each of the first and second terminals also preferably includes at least one tab for crimping onto a wire that carries current to and from the solar cell.

According to another aspect of the invention a solar cell assembly is provided that includes a solar cell having first and second opposing faces. A light concentrator is attached to the second face of the solar cell, which features at least two exposed, opposing, spaced-apart, perimeter areas. The solar cell is mounted in an electrical connector that includes an insulating substrate, a first electrically conductive terminal including a flat plate portion mounted to the insulating substrate, and a second electrically conductive terminal mounted to the insulating substrate. The second terminal includes a U-shaped plate portion that partially circumscribes the first terminal, the U-shaped portion having opposing first and second legs and a web interconnecting the first and second legs. Each leg includes a flexibly resilient wing, the two wings being disposed in opposing relationship. The solar cell is interposed between the first terminal and the wings of the second terminal such that the first terminal abuts the solar cell first face and the wings of the second terminal abut the exposed opposing perimeter areas of the solar cell second face, with the wings resiliently coupling the solar cell to the first and second terminals.

The solar cell assembly preferably also includes wires electrically connected to the first and second terminals, and a grommet connected to the wires. The light concentrator and electrical connector are seated in a pan of a receiver housing. The pan has an aperture therein for the passage of the wires therethrough, where the grommet is shaped to seal the aperture.

Preferably, a heat sink including a plurality of heat radiating fins is mounted to the underside of the receiver housing.

In an embodiment, the first conductive terminal includes flat-domed projections extending from the flat plate portion.

In an embodiment, the first and second terminals are adhesively bonded to the insulating substrate.

In an embodiment, the insulating substrate is a slab of mica.

In an embodiment, each of the first and second terminals includes at least one tab for crimping onto one of the wires.

### BRIEF DESCRIPTION OF THE DRAWINGS

The foregoing and other aspects of the invention will be more readily appreciated having reference to the drawings, wherein:

FIGS. 1A and 1B are perspective views of a solar cell assembly taken from different vantage points;

FIGS. 2A and 2B are exploded and assembly views of an optical subassembly;

FIG. 3 is an isolated perspective view of an electrical connector for connecting a solar cell that forms part of the optical subassembly;

FIG. 4 is an isolated elevation view of the solar cell and optical assembly mounted to the electrical connector; and

FIGS. 5A and 5B are partially exploded views of the solar cell assembly taken from different vantage points.

### DETAILED DESCRIPTION OF THE INVENTION

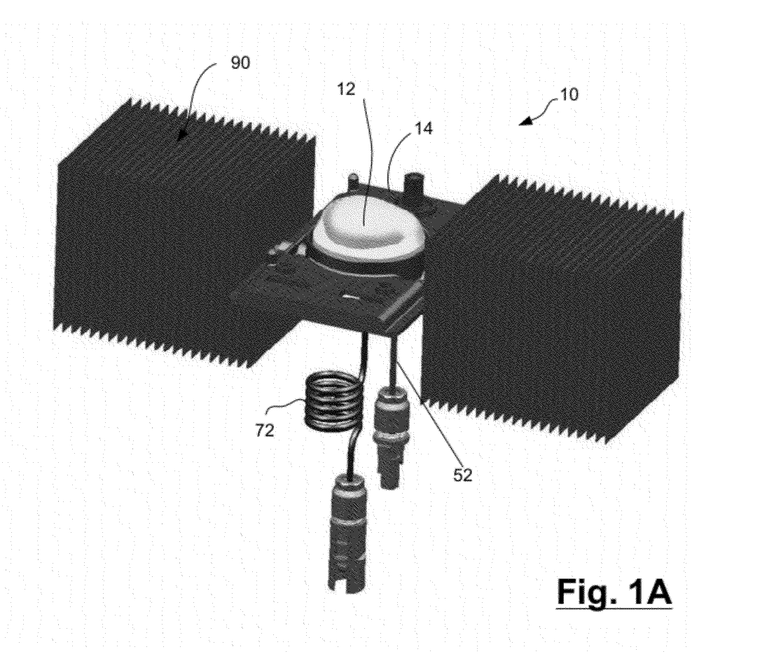

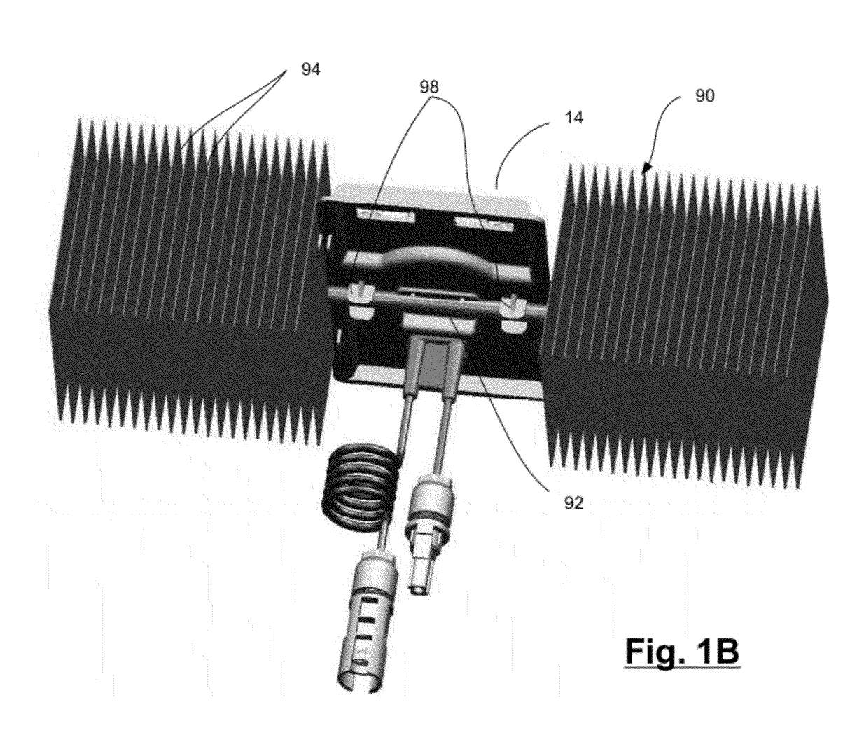

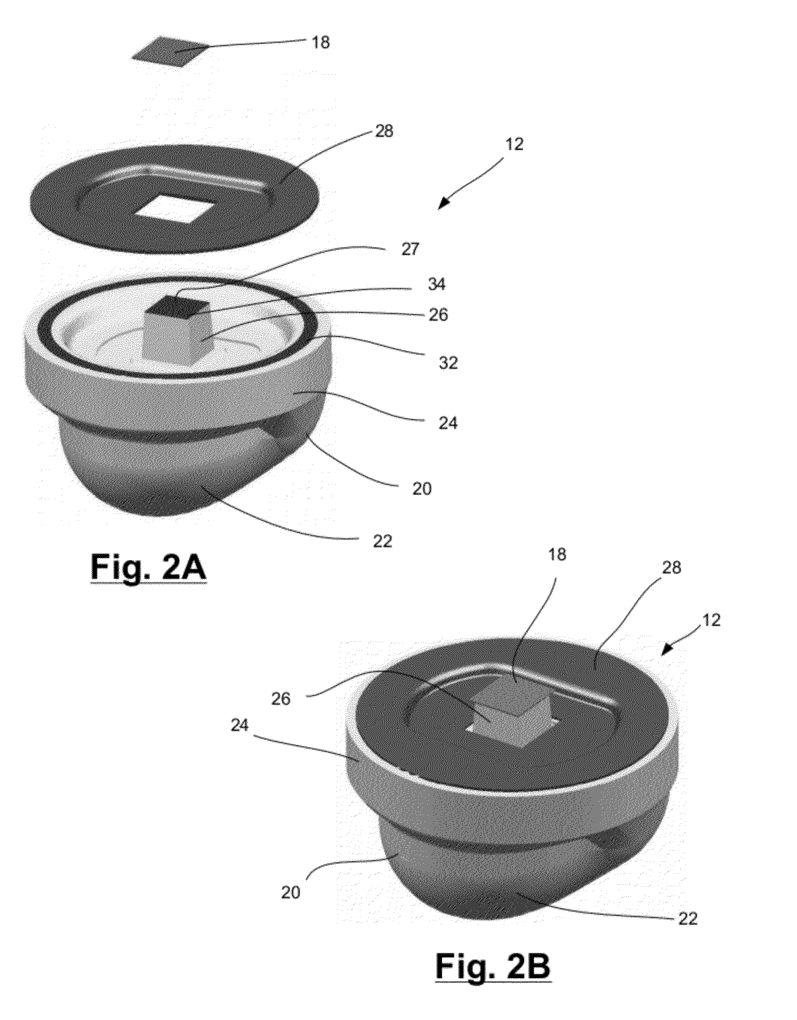

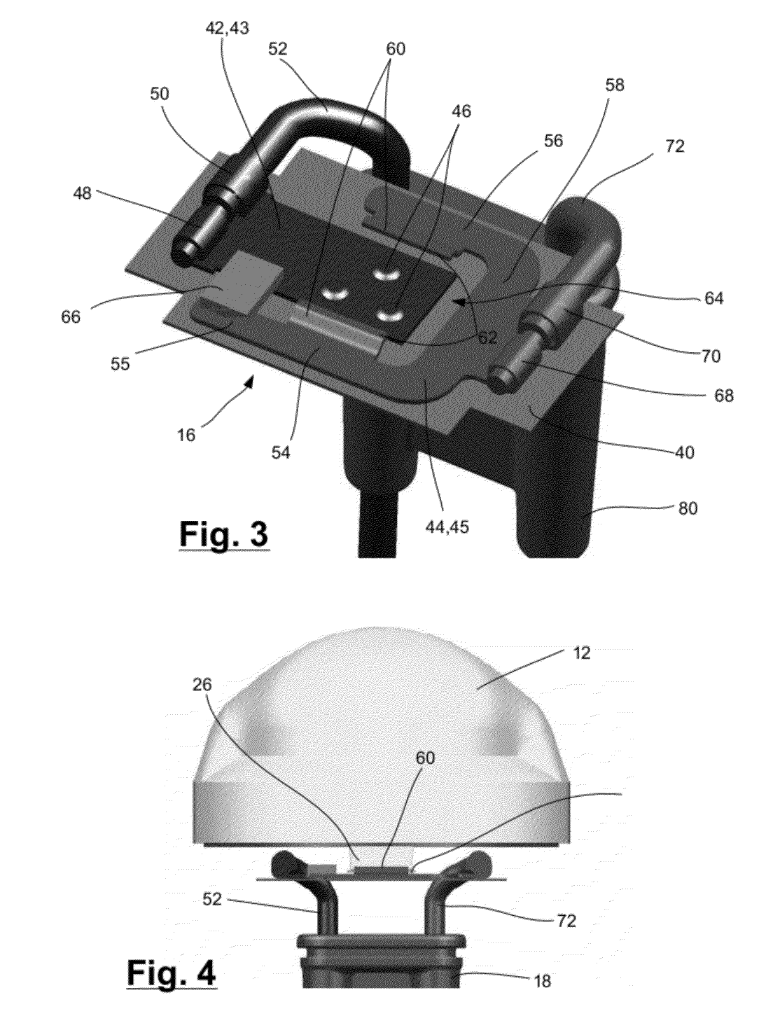

FIGS. 1A and 1B shows a solar cell assembly 10 including an optical subassembly 12 that is mounted to a receiver housing 14. As discussed in greater detail below, the receiver housing 14 also mounts an electrical connector 16 (see FIGS. 3 and 4) that provides a mechanical and electrical connection to a solar cell 18 (see FIGS. 2A, 2B and 4) that forms part of the optical subassembly 12.

More particularly, as seen best in FIGS. 2A and 2B, the optical subassembly 12 includes a light concentrator 20 such as a lens or other optical element. At its top end the concentrator 20 has an active optical surface 22 that is mounted to or otherwise connected to an annulus 24 present at the rear end of the concentrator 20. A tube 26 is formed or otherwise provided at the rear end of the concentrator at or near the center of the annulus 24. The tube 26 has a transparent end surface 27, which preferably extends above a horizontal plane defined by the annulus 24, that represents the focal plane of the light concentrator 20. A solar cell 18 is mounted to the end surface 27 of the tube 26, i.e., at the focal plane, so as to receive the light gathered by the concentrator, and a light shield 28 covers the rear end of the concentrator 20 about the tube 26.

In a preferred assembly sequence, the top end of the concentrator 20 is placed in a fixture nest (not shown), and an adhesive 32 is dispensed onto the rear perimeter of the annulus 24. An adhesive 34 is also dispensed onto the end surface 27 of the tube 26, the latter adhesive 34 being a transparent optical adhesive. A manual manipulator or automated manipulator such as a robot arm (not shown) places the light shield 28 onto the annulus 24. Likewise, a manipulator (not shown) places the solar cell 18 onto the end surface 27 of the tube 26. Depending on the type of adhesive employed, the manipulator may apply pressure to the light shield and/or the solar cell for a limited period of time until the adhesive sets up sufficiently to bond the light shield 28 and/or solar cell 18 to the concentrator 20 without fear of dislodging these parts due to subsequent handling or movement of the optical subassembly 12.

The solar cell 18 is mechanically and electrically connected to the electrical connector 16, which is shown in isolation in FIG. 3. The connector 16 includes an insulating substrate 40, a negative or ground terminal 42 mounted to the insulating substrate 40, and a positive terminal 44 also mounted to the insulating substrate 40.

More particularly, the insulating substrate 40 may be formed from a preferably rigid non-electrically conductive material such as a sheet, layer or slab of mica. The negative terminal 42 is preferably provided in the form of a flat plate 43 with a plurality of preferably flat domed raised dimples or projections that may be formed in the plate via a conventional stamping operation. The underside of the negative terminal 42 is preferably bonded to the insulating substrate 40 utilizing a thermal conductive adhesive as known in the art per se. Two tabs 48, 50 are formed at one end of the negative terminal 42. One tab 48 is curved over and crimped onto a conductive portion of a negative wire 52 to provide an electrical connection to the wire. The other tab 50 is curved over and crimped onto a sheathed portion of the negative wire 52 to provide an additional mechanical fixation to the wire.

The positive terminal 44 is preferably provided as a U-shaped flat plate 45 having a first leg 54, a second leg 56, and an interconnecting web 58. The legs 54,56 each have perpendicularly extending wings 60 that are oriented in opposed relationship. Each wing 60 is bent along two lines in a “staircase” pattern, as may be provided in a stamping operation, so as to provide a lip 62 extending above the negative terminal 42. Collectively, the two wings 60 provide a pocket 64 to seat the solar cell 18 as shown in FIG. 4., with one side of the solar cell 18 abutting the negative terminal 42 and the other side of the solar cell 18 contacting the positive terminal 44 via the wing lips 62.

The first linear segment 54 also includes an extension portion 55. A diode 66 is connected between the positive terminal extension portion 55 and the negative terminal 42. The diode 66 provides continuity in the event the solar cell 18 is installed in a serial circuit so as to preclude an open circuit situation.

The web end 58 of the positive terminal 42 includes two tabs 68, 70, one of which (68) is crimped onto a conductive portion of a positive wire 72 and the other of which (70) is crimped onto a sheathed portion of the positive wire 72. As discussed in greater detail below, the underside of the positive terminal 44 is also preferably bonded to the insulating substrate 40 utilizing a thermally conductive adhesive.

In a preferred assembly sequence, thermal adhesive is applied to the insulating substrate 40 in the areas spanning the footprint or placement of the negative and positive terminals 42, 44. The negative terminal 42 is first attached to the insulating substrate 40. Then, the optical subassembly 12 is mounted to the electrical connector 16 such that one face, i.e, the negative side, of the solar cell 18 is disposed atop and contacts the projections 46 of the negative terminal 42. Next, the positive terminal 44 is positioned over the insulating substrate 40 such that the lips 62 of the wings 60 overlie the other face, i.e., the positive side, of the solar cell 18. For this reason it is preferred that the solar cell 18 have a breadth somewhat larger than that the breadth of the tube end surface 27 thus leaving at least two exposed opposing perimeter areas on the positive side of the solar cell that can be gripped by the wings 60. Once the positive terminal 44 is properly positioned and aligned a manual or mechanical manipulator (not shown) applies pressure between the positive terminal 44 and the insulating substrate 40 until the adhesive is sufficiently cured to lock the solar cell 18 and the optical subassembly 12 between the positive terminal and the negative terminal/insulating substrate.

In preferred embodiments, the height of the pocket 64 is preferably a little thinner than the thickness of the solar cell. In particular, the distance between the tops of the domed projections (which are preferably located on the same plane) and the underside of the lip 62 is preferably a little smaller than the thickness of the solar cell. It should be appreciated that the wings 60 provide a resilient coupling member in that the wings 60 are somewhat resiliently flexible and thus function essentially like leaf springs which, when mounted, ensure good contact between the terminals 42, 44 and the faces of the solar cell. It will also be understood that the wings 60 may be provided in other shapes and forms so as to provide an alternative resilient coupling member. For example, each wing 60 may be formed to have only one bend in it instead of the two bends providing the illustrated staircase pattern. In another alternative, each wing 60 may be formed as a straight tab extending from the leg with no bends therein, wherein the tab functions as a leaf spring due to the inherent characteristic of a plate to retain a flat shape. Suitable materials for the positive and negative terminals include copper, brass, and/or stainless steel.

Due to the size and shape of the optical subassembly 12 the positive and negative terminals 42, 44 are preferably crimped onto the positive and negative wires 52, 72 as discussed above prior to bonding the terminals 42, 44 onto the insulating substrate 40. However, the diode 66 is connected after the positive and negative terminals 42, 44 are attached to the insulating substrate 40.

The wires 52 and 72 are preferably connected to a grommet 80 that provides a sealing function, as discussed in greater detail below, and provides strain relief. The grommet 80 may be over-molded onto the wires 52, 72 prior to their fixation to the positive and negative terminals 42, 44, or the wires 52, 72 may be threaded through apertures in the grommet.

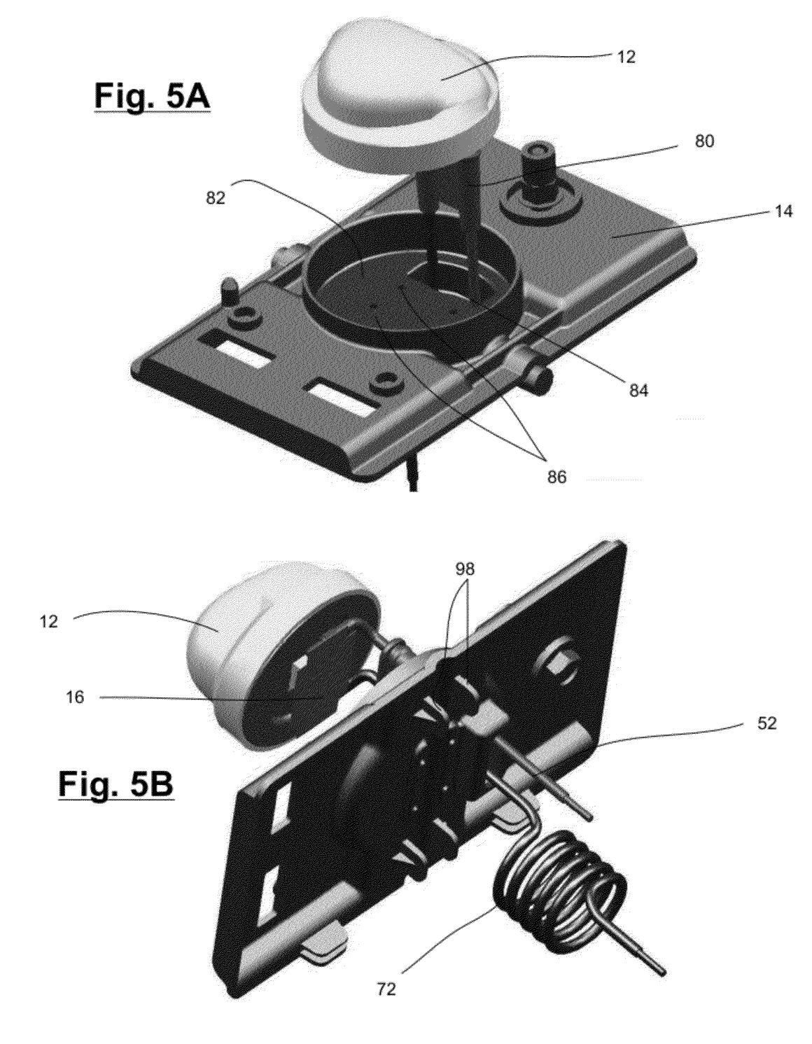

Referring additionally to FIGS. 5A and 5B, once the optical subassembly 12 is attached to the electrical connector 16, these components are mounted to the receiver housing 14.

The receiver housing 14 is preferably formed from a thermally conductive material such as aluminum that may be manufactured using known casting processes. The receiver housing 14 is preferably formed to incorporate an pan 82 therein. The pan 82 is sized to receive and seat the annulus 24 of the concentrator 20. The pan 82 also includes an aperture 84 therein which is shaped to matingly and snugly fit the grommet 80 to thus seal the bottom of the pan whilst allowing for the passage of the wires 52, 72 therethrough. The bottom of the pan 82 preferably also includes a series of holes 86 therein for screws or bolts (not shown) to secure the insulating substrate 40 to the receiver housing 14.

As seen best in FIGS. 1A and 1B a heat sink 90 is also mounted to the bottom of the receiver housing 14. The heat sink 90 includes a main shank 92 that interconnects a number of radiating fins 94. The central portion of the shank 92 is bare and mounts to a channel 96 formed on the underside of the receiver housing by a series of mounting abutments 98 integrally formed in the housing. The shank 92 is preferably bonded to the underside of the receiver housing 14 and the abutments 98 by thermal adhesive, although other well known attachment mechanisms may be utilized in the alternative.

From the foregoing description it will be seen that the exemplary embodiments described herein eliminate the need for a printed circuit board and its attendant soldering processes. Instead, the electrical connector 16 provides a practical alternative that is believed to be easier to assemble at a lower cost using conventional industrial equipment.

While the above describes a particular embodiment(s) of the invention, it will be appreciated that modifications and variations may be made to the detailed embodiment(s) described herein without departing from the spirit of the invention.

1. An electrical connector for mounting a solar cell having first and second opposing faces, the connector comprising:
an insulating substrate;
a first electrically conductive terminal including a flat plate portion mounted to the insulating substrate;
a second electrically conductive terminal mounted to the insulating substrate, the second terminal comprising a U-shaped plate portion that partially circumscribes the first terminal, the U-shaped portion having opposing first and second legs and a web interconnecting the first and second legs, wherein each leg includes a flexibly resilient wing, the two wings being disposed in opposing relationship so as to provide a resilient coupling member when a solar cell is interposed between the first terminal and the wings of the second terminal such that the first face of the solar cell abuts the first terminal and a portion of the second face of the solar cell abuts the wings of the second terminal.

2. A connector according to claim 1, wherein the first conductive terminal includes flat-domed projections extending from the flat plate portion.

3. A connector according to claim 1, wherein the first and second terminals are adhesively bonded to the insulating substrate.

4. A connector according to claim 1, wherein the insulating substrate is a slab of mica.

5. A connector according to claim 1, wherein each wing has two bends therein to form a staircase pattern, the staircase pattern having a distal lip that is disposed in a different plane than the flat plate portion of the first terminal.

6. A connector according to claim 1, wherein each wing has a single bend therein to form a distal lip that is disposed in a different plane than the flat plate portion of the first terminal.

7. A connector according to claim 1, wherein each wing is formed as a straight extension of the corresponding first or second leg, the wing having a distal lip that is disposed in a different plane than the flat plate portion of the first terminal when the solar cell is mounted in the connector.

8. A connector according to claims 5, wherein the distance between an uppermost surface of the first terminal and the lip is less than the thickness of the solar cell.

9. A connector according to claim 1, wherein each of the first and second terminals includes at least one tab for crimping onto a wire.

10. A solar cell assembly, comprising:
a solar cell having first and second opposing faces;
a light concentrator attached to the second face of the solar cell, said second face having at least two exposed, opposing, spaced-apart perimeter areas;
an electrical connector comprising an insulating substrate, a first electrically conductive terminal including a flat plate portion mounted to the insulating substrate, and a second electrically conductive terminal mounted to the insulating substrate, the second terminal comprising a U-shaped plate portion that partially circumscribes the first terminal, the U-shaped portion having opposing first and second legs and a web interconnecting the first and second legs, wherein each leg includes a flexibly resilient wing, the two wings being disposed in opposing relationship;
wherein the solar cell is interposed between the first terminal and the wings of the second terminal such that the first terminal abuts the solar cell first face and the wings of the second terminal abut the exposed opposing perimeter areas of the solar cell second face, said wings resiliently coupling the solar cell to the first and second terminals.

11. A solar cell assembly according to claim 10, including:
wires electrically connected to the first and second terminals;
a grommet connected to the wires;
a receiver housing having a pan for seating the light concentrator and electrical connector, the pan having an aperture therein for the passage of the wires therethrough, the grommet being shaped to seal the aperture.

12. A solar cell assembly according to claim 11, including a heat sink mounted to the receiver housing, the heat sink including a plurality of heat radiating fins.

13. A solar cell assembly according to claim 11, wherein the first conductive terminal includes flat-domed projections extending from the flat plate portion.

14. A solar cell assembly according to claim 11, wherein the first and second terminals are adhesively bonded to the insulating substrate.

15. A solar cell assembly according to claim 11, wherein the insulating substrate is a slab of mica.

16. A solar cell assembly according to claim 11, wherein each wing is formed according to one of the following:
(a) each wing has two bends therein to form a staircase pattern, the staircase pattern having a distal lip that is disposed in a different plane than the flat plate portion of the first terminal;
(b) each wing has a single bend therein to form a distal lip that is disposed in a different plane than the flat plate portion of the first terminal; or
(c) each wing is formed as a straight extension of the corresponding first or second leg, the wing having a distal lip that is disposed in a different plane than the flat plate portion of the first terminal when the solar cell is mounted in the connector.

17. A solar cell assembly according to claim 16, where the distance between an uppermost surface of the first terminal and the lip is less than the thickness of the solar cell.

18. A solar cell assembly according to claim 11, wherein each of the first and second terminals includes at least one tab for crimping onto one of the wires.

19. A connector according to claim 6, wherein the distance between an uppermost surface of the first terminal and the lip is less than the thickness of the solar cell.

20. A connector according to claim 7, wherein the distance between an uppermost surface of the first terminal and the lip is less than the thickness of the solar cell.
